(19) United States
(12) Patent Application Publication
(10) Pub. No.: US 2026/0120600 A1
(43) Pub. Date: Apr. 30, 2026

(54) DISPLAY DEVICE AND METHOD OF INSPECTING DISPLAY DEVICE, AND ELECTRONIC DEVICE

(71) Applicant: Samsung Display Co., LTD., Yongin-si (KR)

(72) Inventors: Seok Gi BAEK, Yongin-si (KR); Ki Hoon LEE, Yongin-si (KR); Du Hyun KIM, Yongin-si (KR)

(21) Appl. No.: 19/262,263

(22) Filed: Jul. 8, 2025

(30) Foreign Application Priority Data
Oct. 29, 2024 (KR) 10-2024-0149690

(51) Int. Cl. G09G 3/00; G01R 31/28; G09G 3/32; G09G 3/3233

(52) U.S. Cl. CPC G09G 3/006; G01R 31/2825; G09G 3/3233; G09G 3/32; G09G 2300/0819; G09G 2300/0842; G09G 2300/0861; G09G 2310/08; G09G 2330/02; G09G 2330/12

(57) ABSTRACT

In a method of inspecting a display device including a pixel, the method includes: supplying different voltages to a gate electrode of a driving transistor of the pixel for different frames; and sensing an amount of current flowing through the driving transistor while allowing a switching transistor, of the pixel, connected between a data line and a first electrode of the driving transistor to be turned on during a partial period for each frame, where a diode transistor, of the pixel, located between the gate electrode and a second electrode of the driving transistor is set to be in a turn-off state.

The application claims priority to Korean patent application No. 10-2024-0149690, filed on Oct. 29, 2024, and all the benefits accruing therefrom under 35 U.S.C. § 119, the content of which in its entirety is herein incorporated by reference.

### BACKGROUND

### 1. Technical Field

The disclosure generally relates to a display device and a method of inspecting a display device, and an electronic device.

### 2. Related Art

With the development of information technologies, the importance of a display device which is a connection medium between a user and information increases. Accordingly, display devices such as a liquid crystal display device and an organic light emitting display device are increasingly used.

An inspection process for inspecting whether pixels are abnormal is included in a processing process (manufacturing process) of a display device. A method capable of stably detecting whether pixels are abnormal in the inspection process is desirable.

### SUMMARY

Embodiments provide a display device and a method of inspecting a display device, and an electronic device, in which whether pixels are abnormal can be stably detected.

In accordance with an aspect of the disclosure, there is provided a method of inspecting a display device, where the display device includes pixels each including: a first transistor including a gate electrode connected to a first node, a first electrode connected to a first power line via a second node, and a second electrode connected to a third node; a second transistor connected between a data line and the second node, the second transistor including a gate electrode connected to a first scan line; a third transistor connected between the first node and the third node, the third transistor including a gate electrode connected to a second scan line; a fourth transistor connected between the first node and a second power line, the fourth transistor including a gate electrode connected to a third scan line; a fifth transistor connected between the third node and a third power line, the fifth transistor including a gate electrode connected to a fourth scan line; and a sixth transistor connected between the second node and a fourth power line, the sixth transistor including a gate electrode connected to the fourth scan line, and during an inspection process of the pixels, a first voltage is supplied to the data line, the first power line, and the fourth power line, a second voltage is supplied to the third power line, and a voltage decreased from a third voltage to a fourth voltage is supplied to the second power line; and a gate-off voltage is supplied to the second scan line such that the third transistor is turned off.

The first voltage may be 0 voltage (V).

The second voltage may be a voltage lower than the first voltage.

The third voltage may be a voltage higher than the first voltage, and the fourth voltage may be a voltage lower than the second voltage.

The voltage supplied to the second power line may be decreased by a certain voltage for each frame.

Each of the pixels may further include: a seventh transistor connected between the first power line and the second node, the seventh transistor including a gate electrode connected to an emission control line; and an eighth transistor connected between the third node and the fifth transistor, the eighth transistor including a gate electrode connected to the emission control line.

During the inspection process, an enable first scan signal may be supplied to the first scan line such that the second transistor is turned on at least once in a frame period. During the inspection process, a gate-on voltage may be supplied to the third scan line such that the fourth transistor is turned on.

An enable emission control signal may be supplied to the emission control line to overlap with the enable first scan signal in time such that the seventh transistor and the eighth transistor are turned on during a partial period of the frame period, and a disable emission control signal may be supplied to the emission control line such that the seventh transistor and the eighth transistor are turned off during a remaining period of the frame period.

The remaining period may be 95% to 99% of the frame period.

An enable fourth scan signal may be supplied to the fourth scan line such that the sixth transistor is turned on during the partial period, and a disable fourth scan signal may be supplied to the fourth scan line such that the sixth transistor is turned off during the remaining period.

The first voltage may be supplied to the first power line via a first resistor. The first voltage may be supplied to the fourth power line via a second resistor.

The first resistor and the second resistor may each have a resistance value of 100 ohms (Ω) to 100 megaohms (MΩ).

In accordance with another aspect of the disclosure, there is provided a method of inspecting a display device including a pixel, the method including: supplying different voltages to a gate electrode of a driving transistor of the pixel for different frames; and sensing an amount of current flowing through the driving transistor while allowing a switching transistor, of the pixel, connected between a data line and a first electrode of the driving transistor to be turned on during a partial period for each frame, and a diode transistor, of the pixel, located between the gate electrode and a second electrode of the driving transistor is set to be in a turn-off state.

A first voltage may be supplied to a first power line and a bias power line, which are electrically connected to the first electrode of the driving transistor.

The first voltage may be supplied to the data line.

The first voltage may be supplied to the first power line via a first resistor. The first voltage may be supplied to the bias power line via a second resistor.

The first resistor and the second resistor may each have a resistance value of 100Ω to 100 MΩ.

In accordance with still another aspect of the disclosure, there is provided a display device including a pixel unit including pixels, which display an image, and a test pixel, which does not display the image. The test pixel includes: a first transistor including a gate electrode connected to a first node, a first electrode connected to a second node, and a second electrode connected to a third node; a storage capacitor connected between a first power line and the first node; a second transistor connected between a data line and the second node, the second transistor including a gate electrode connected to a first scan line; a third transistor connected between the first node and the third node, the third transistor including a gate electrode connected to a second scan line; a fourth transistor connected between the first node and a second power line, the fourth transistor including a gate electrode connected to a third scan line; a fifth transistor connected between the third node and a third power line, the fifth transistor including a gate electrode connected to a fourth scan line; a sixth transistor including a second electrode connected to the second node and a gate electrode connected to the fourth scan line; a seventh transistor including a second electrode connected to the second node and a gate electrode connected to an emission control line; and an eighth transistor connected between the third node and the fifth transistor, the eighth transistor including a gate electrode connected to the emission control line, and a first electrode of the seventh transistor is not electrically connected to the first power line.

A first electrode of the sixth transistor may not be electrically connected to a separate power line.

In accordance with still another aspect of the disclosure, there is provided an electronic device including a display panel including pixels, which display an image, and a test pixel, which does not display the image. The test pixel includes: a first transistor including a gate electrode connected to a first node, a first electrode connected to a second node, and a second electrode connected to a third node; a storage capacitor connected between a first power line and the first node; a second transistor connected between a data line and the second node, the second transistor including a gate electrode connected to a first scan line; a third transistor connected between the first node and the third node, the third transistor including a gate electrode connected to a second scan line; a fourth transistor connected between the first node and a second power line, the fourth transistor including a gate electrode connected to a third scan line; a fifth transistor connected between the third node and a third power line, the fifth transistor including a gate electrode connected to a fourth scan line; a sixth transistor including a second electrode connected to the second node and a gate electrode connected to the fourth scan line; a seventh transistor including a second electrode connected to the second node and a gate electrode connected to an emission control line; and an eighth transistor connected between the third node and the fifth transistor, the eighth transistor including a gate electrode connected to the emission control line, and a first electrode of the seventh transistor is not electrically connected to the first power line.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a display device in accordance with an embodiment of the disclosure.

FIG. 2 is a diagram illustrating an embodiment of a scan driver and an emission driver, which are shown in FIG. 1.

FIG. 3 is a diagram illustrating a pixel in accordance with an embodiment of the disclosure.

FIG. 4 is a waveform diagram illustrating an embodiment of a method of driving the pixel shown in FIG. 3 during a display scan period.

FIG. 5 is a waveform diagram illustrating an embodiment of a method of driving the pixel shown in FIG. 3 during a self-scan period.

FIGS. 6 and 7 are diagrams illustrating an embodiment of signals supplied in an active period and a blank period.

FIG. 8 is a diagram illustrating an embodiment of a voltage supplied to pixels in an inspection process of the pixels.

FIGS. 9A and 9B are diagrams illustrating driving waveforms supplied to the pixels in the inspection process.

FIG. 10 is a diagram illustrating an example of an emission control signal supplied during an inspection period.

FIG. 11 is a diagram illustrating a characteristic curve of a first transistor, which is detected in the inspection process.

FIG. 12 is a diagram illustrating an embodiment in which a voltage is supplied to pixels in an inspection process of the pixels.

FIG. 13 is a diagram illustrating a characteristic curve of the first transistor, which is generated in the inspection process, in case that the voltage is supplied via a resistor as shown in FIG. 12.

FIG. 14 is a diagram illustrating a test pixel in accordance with an embodiment of the disclosure.

FIG. 15 is a diagram illustrating an electronic device in accordance with an embodiment of the disclosure.

### DETAILED DESCRIPTION

Hereinafter, exemplary embodiments are described in detail with reference to the accompanying drawings so that those skilled in the art may easily practice the disclosure. The disclosure may be implemented in various different forms and is not limited to the exemplary embodiments described in the specification.

A part irrelevant to the description will be omitted to clearly describe the disclosure, and the same or similar constituent elements will be designated by the same reference numerals throughout the specification. Therefore, the same reference numerals may be used in different drawings to identify the same or similar elements.

In description, the expression “equal” may mean “substantially equal.” That is, this may mean equality to a degree to which those skilled in the art can understand the equality. Other expressions may be expressions in which “substantially” is omitted.

Some embodiments are described in the accompanying drawings in relation to functional blocks, units, and/or modules. Those skilled in the art will understand that these blocks, units, and/or modules are physically implemented by logic circuits, individual components, microprocessors, hard wire circuits, memory elements, line connection, and other electronic circuits. This may be formed by using semiconductor-based manufacturing techniques or other manufacturing techniques. In the case of blocks, units, and/or modules implemented by microprocessors or other similar hardware, the units, and/or modules are programmed and controlled by using software, to perform various functions discussed in the disclosure, and may be selectively driven by firmware and/or software. In addition, each block, each unit, and/or each module may be implemented by dedicated hardware or by a combination dedicated hardware to perform some functions of the block, the unit, and/or the module and a processor (e.g., one or more programmed microprocessors and associated circuitry) to perform other functions of the block, the unit, and/or the module. In some embodiments, the blocks, the units, and/or the modules may be physically separated into two or more individual blocks, two or more individual units, and/or two or more individual modules without departing from the scope of the disclosure. Also, in some embodiments, the blocks, the units, and/or the modules may be physically separated into more complex blocks, more complex units, and/or more complex modules without departing from the scope of the disclosure.

The term “connection” between two components may include both electrical connection and physical connection, but the disclosure is not necessarily limited thereto. For example, the term “connection” used based on circuit diagrams may mean electrical connection, and the term “connection” used based on sectional and plan views may mean physical connection. Similarly, it will be understood that when an element is referred to as being “connected to” another element, it can be directly connected to the other element or intervening elements may be present therebetween. In contrast, when an element is referred to as being “directly connected to” another element, there are no intervening elements present.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure.

The disclosure is not limited to embodiments disclosed below, and may be implemented in various forms. Each embodiment disclosed below may be independently embodied or be combined with at least another embodiment prior to being embodied.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

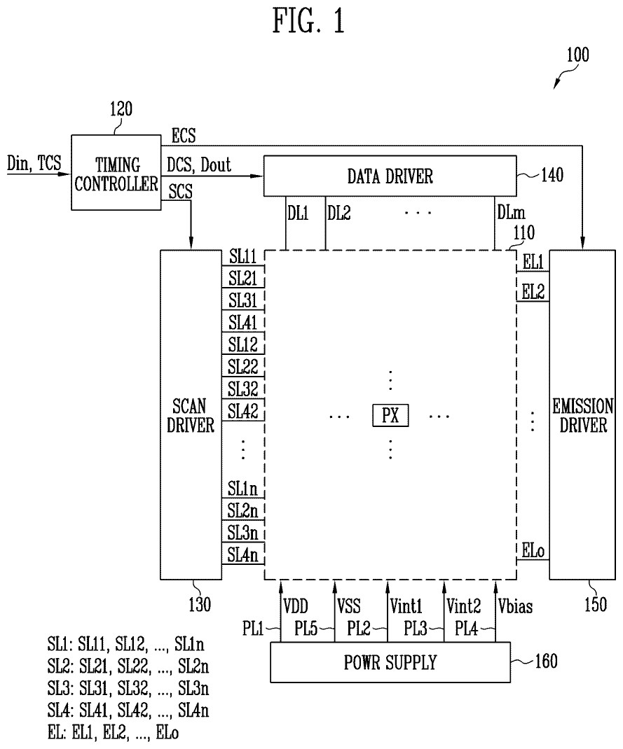

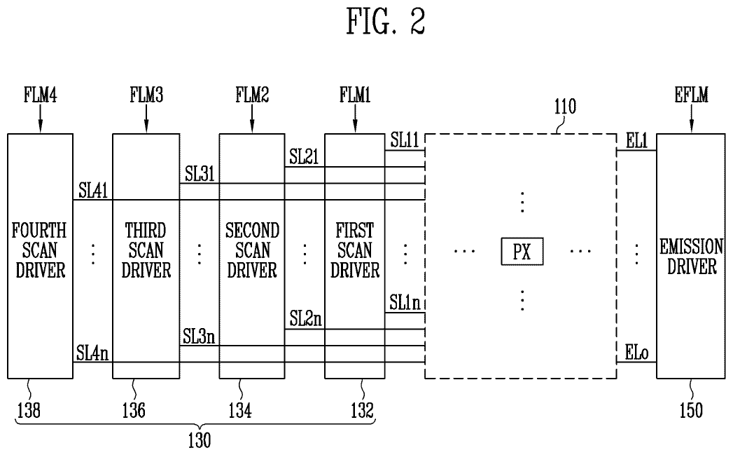

FIG. 1 is a diagram illustrating a display device in accordance with an embodiment of the disclosure. FIG. 2 is a diagram illustrating an embodiment of a scan driver and an emission driver, which are shown in FIG. 1.

Referring to FIG. 1, a display device 100 in accordance with an embodiment of the disclosure may include a pixel unit 110 (or display panel), a timing controller 120, a scan driver 130, a data drier 140, an emission driver 150, and a power supply 160.

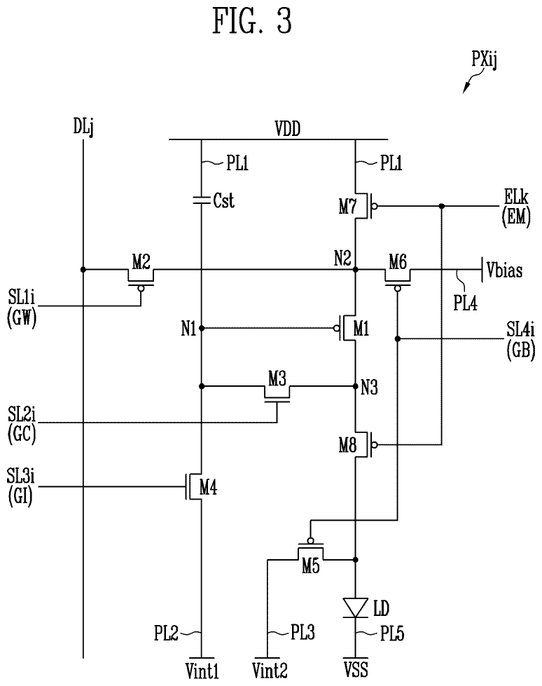

The display device 100 may display an image at various image refresh rates (or driving frequencies or screen refresh rates) according to driving conditions. The image refresh rate means a frequency at which a data signal is written to a driving transistor (i.e., first transistor M1 in FIGS. 3, 8, 12 and 14) of a pixel PX. For example, the image refresh rate may also be referred to as a screen scan rate or a screen refresh frequency, and represent a frequency at which a display screen is reproduced for one second.

In an embodiment, an output frequency of the data driver 140 and/or an output frequency of a first scan driver 132 which outputs a first scan signal (or write scan signal) with respect to a horizontal line (e.g., pixels PX connected to the same scan line may be sorted as a horizontal line (or pixel row)) may be determined corresponding to the image refresh rate. For example, an image refresh rate for driving a moving image may be a frequency of about 60 Hz or higher (e.g., 120 Hz, 240 Hz, 360 Hz or the like).

For example, the display device 100 may display an image, corresponding to various image refresh rates of 1 Hz to 360 Hz. However, this is merely illustrative, and the display device 100 may also display an image at an image refresh rate of 360 Hz or higher (e.g., 480 Hz).

The pixel unit 110 may include pixels PX connected to first scan lines SL11, SL12, . . . , and SL1n, second scan lines SL21, SL22, . . . , and SL2n, third scan lines SL31, SL32, . . . , and SL3n, fourth scan lines SL41, SL42, . . . , and SL4n, data lines DL1, DL2, . . . , and DLm, emission control lines EL1, EL2, . . . , and ELo, and power lines PL1, PL2, PL3, PL4, and PL5 (n, m, and o are natural numbers of 2 or more).

In an example, a pixel PXij (see FIG. 3) located on an ith horizontal line (or pixel row) and a jth vertical line (or pixel column) may be connected to an ith first scan line SL1i, an ith second scan line SL2i, an ith third scan line SL3i, an ith fourth scan line SL4i, a kth emission control line ELk, and a jth data line DLj (i is a natural number of n or less, j is a natural number of m or less, and k is a natural number of o more less). Here, k may be a number which is equal to i or is smaller than i. In an example, in case that each of the emission control lines EL1 to ELo is connected to pixels PX located on a horizontal line, k and i may be a same number. In an example, in case that each of the emission control lines EL1 to ELo is connected to pixels PX located on two or more horizontal lines, k may be a number smaller than i.

Pixels PX may be selected in a horizontal line unit in case that an enable first scan signal is supplied to the first scan lines SL11 to SL1n. The pixels PX selected by the enable first scan signal may be supplied with a data signal from a data line (any one of DL1 to DLm) connected thereto. The pixel PX supplied with the data signal may generate light with a luminance corresponding to a voltage of the data signal.

The scan driver 130 may receive a scan driving signal SCS from the timing controller 120. At least one scan start signal and clock signals, which are for driving of the scan driver 130, may be included in the scan driving signal SCS. The scan driver 130 may generate an enable first scan signal, an enable second scan signal, an enable third scan signal, and an enable fourth scan signal while shifting the scan start signal, corresponding to a clock signal.

To this end, the scan driver 130 may include the first scan driver 132, a second scan driver 134, a third scan driver 136, and a fourth scan driver 138 as shown in FIG. 2. At least some of the scan drivers 132, 134, 136, and 138 may be integrated into a single driving circuit, a single module, or the like according to a design.

The first scan driver 132 may receive a first scan start signal FLM1, and generate an enable first scan signal while shifting the first scan start signal FLM1, corresponding to a clock signal. The first scan driver 132 may sequentially supply the enable first scan signal to the first scan lines SL11 to SL1n. In an embodiment, the first scan driver 132 may supply an enable first scan signal during a display scan period of a frame.

The second scan driver 134 may receive a second scan start signal FLM2, and generate an enable second scan signal while shifting the second scan start signal FLM2, corresponding to a clock signal. The second scan driver 134 may sequentially supply the enable second scan signal to second scan lines SL21 to SL2n. The second scan driver 134 may supply an enable second scan signal during a display scan period of a frame.

The third scan driver 136 may receive a third scan start signal FLM3, and generate an enable third scan signal while shifting the third scan start signal FLM3, corresponding to a clock signal. The third scan driver 136 may sequentially supply the enable third scan signal to third scan lines SL31 to SL3n. The third scan driver 136 may supply an enable third scan signal during a display scan period of a frame.

The fourth scan driver 138 may receive a fourth scan start signal FLM4, and generate an enable fourth scan signal while shifting the fourth scan start signal FLM4, corresponding to a clock signal. The fourth scan driver 138 may sequentially supply the enable fourth scan signal to fourth scan lines SL41 to SL4n.

In an embodiment, the fourth scan driver 138 may supply an enable fourth scan signal during a display scan period and a self-scan period of a frame. For example, the fourth scan driver 138 may perform scanning once (i.e., supply at least one enable fourth scan signal) during the display scan period, and perform scanning at least once according to an image refresh rate during the self-scan period. In case that the image refresh rate is decreased (i.e., in case that a frame length is lengthened), the number of times an operation of supplying, by the fourth scan driver 138, an enable fourth scan signal to each of the fourth scan lines SL41 to SL4n in a frame period is repeated may be increased.

The enable first scan signal, the enable second scan signal, the enable third scan signal, and the enable fourth scan signal may be set to a gate-on voltage such that transistors included in the pixels PX can be turned on.

In an example, an enable first scan signal GW and an enable fourth scan signal GB, which are supplied to a P-type transistor as shown in FIG. 3, may be set to a logic low level voltage. In an embodiment, an enable second scan signal GC and an enable third scan signal GI, which are supplied to an N-type transistor, may be set to a logic high level voltage.

In FIG. 2, it is illustrated that the first scan driver 132, the second scan driver 134, the third scan driver 136, and the fourth scan driver 138 are connected to a first scan line SL1, a second scan line SL2, a third scan line SL3, and a fourth scan line SL4, respectively. However, the embodiment of the disclosure is not limited thereto. In another example, at least two scan lines among the first scan line SL1, the second scan line SL2, the third scan line SL3, and the fourth scan line SL4 (i.e., at least two of SL1, SL2, SL3, and SL4) may be driven by one scan driver.

The data driver 140 may receive output data Dout and a data driving signal DCS from the timing controller 120. The data driving signal DCS may include a sampling signal and/or timing signals, for driving of the data driver 140. The data driver 140 may generate a data signal, based on the data driving signal DCS and the output data Dout. In an example, the data driver 140 may generate an analog data signal, based on a grayscale of the output data Dout. The data driver 140 may supply the data signal in a horizontal period unit.

The emission driver 150 may receive an emission driving signal ECS from the timing controller 120. An emission start signal and clock signals, which are for driving the emission driver 150, may be included in the emission driving signal ECS. The emission driver 150 may generate a disable emission control signal EM while shifting the emission start signal, corresponding to a clock signal.

As shown in FIG. 2, the emission driver 150 may receive an emission start signal EFLM, and generate a disable emission control signal EM by shifting the emission start signal EFLM, corresponding to a clock signal. The emission driver 150 may sequentially supply the disable emission control signal EM to the emission control lines EL1 to ELo. The disable emission control signal EM may be set to a gate-off voltage such that the transistors included in the pixels PX can be turned off. In an example, a disable emission control signal EM supplied to a P-type transistor as shown in FIG. 3 may be set to a logic high level voltage.

In an embodiment, the emission driver 150 may supply a disable emission control signal EM during a display scan period and a self-scan period of a frame. For example, the emission driver 150 may perform scanning once during the display scan period, and perform scanning at least once according to an image refresh rate during the self-scan period. In case that the image refresh rate is decreased (i.e., in case that a frame length is lengthened), the number of times an operation of supplying, by the emission driver 150, a disable emission control signal EM to each of the emission control lines EL1 to ELo in a frame period is repeated may be increased.

The timing controller 120 may receive input data Din and a timing control signal TCS from a host system through an interface. In an example, the timing controller 120 may receive the input data Din and the timing control signal TCS from at least one of a Graphics Processing Unit (GPU), a Central Processing Unit (CPU), and an Application Processor (AP), which are included in the host system. Various signals including a clock signal may be included in the timing control signal TCS.

The timing controller 120 may generate the scan driving signal SCS, the data driving signal DCS, and the emission driving signal ECS, based on the timing control signal TCS. The scan driving signal SCS, the data driving signal DCS, and the emission driving signal ECS may be supplied to the scan driver 130, the data driver 140, and the emission driver 150, respectively.

The timing controller 120 may realign the input data Din to be suitable for specifications of the display device 100. Also, the timing controller 120 may generate the output data Dout by correcting the input data Din, and supply the output data Dout to the data driver 140. In an embodiment, the timing controller 120 may correct the input data Din, corresponding to an optical measurement result measured in a processing process.

The power supply 160 may generate various power sources for driving of the display device 100. In an example, the power supply 160 may generate a first driving power source VDD, a second driving power source VSS, a first initialization power source Vint1, a second initialization power source Vint2, and a bias power source Vbias.

The first driving power source VDD may be a power source which supplies a driving current to the pixels PX. The second driving power source VSS may be a power source which is supplied with the driving current from the pixels PX. The first driving power source VDD may be set to a voltage higher than a voltage of the second driving power source VSS during a period in which the pixels PX are set to be in an emission state.

The first initialization power source Vint1 may be a power source for initializing a gate electrode of a driving transistor (i.e., first transistor M1 in FIGS. 3, 8, 12 and 14) included in each of the pixels PX. The first initialization power source Vint1 may be set to a voltage lower than the data signal. The second initialization power source Vint2 may be a power source for initializing a first electrode (or anode electrode) of a light emitting element LD (see FIG. 3) included in each of the pixels PX. The second initialization power source Vint2 may be set to a voltage at which the light emitting element LD is turned off. The bias power source Vbias may be a power source for applying an on-bias voltage to the driving transistor (i.e., first transistor M1 in FIGS. 3, 8, 12 and 14) included in each of the pixels PX.

The first driving power source VDD generated by the power supply 160 may be supplied to a first power line PL1, the second driving power source VSS generated by the power supply 160 may be supplied to a fifth power line PL5, the first initialization power source Vint1 generated by the power supply 160 may be supplied to a second power line PL2, the second initialization power source Vint2 generated by the power supply 160 may be supplied to a third power line PL4, and the bias power source Vbias generated by the power supply 160 may be supplied to a fourth power line PL4. The first power line PL1, the second power line PL2, the third power line PL3, the fourth power line PL4, and the fifth power line PL5 may be commonly connected to the pixels PX, but the embodiment of the disclosure is not limited thereto.

In an embodiment, the first power line PL1 may be configured with a plurality of power lines, and the plurality of power lines may be connected to different pixels PX. In an embodiment, the second power line PL2 may be configured with a plurality of power lines, and the plurality of power lines may be connected to different pixels PX. In an embodiment, the third power line PL3 may be configured with a plurality of power lines, and the plurality of power lines may be connected to different pixels PX. In an embodiment, the fourth power line PL4 may be configured with a plurality of power lines, and the plurality of power lines may be connected to different pixels PX. In an embodiment, the fifth power line PL5 may be configured with a plurality of power lines, and the plurality of power lines may be connected to different pixels PX. For example, in an embodiment of the disclosure, each of the pixels PX may be connected to any one of the plurality of power lines constituting the first power line PL1, any one of the plurality of power lines constituting the second power line PL2, any one of the plurality of power lines constituting the third power line PL3, any one of the plurality of power lines constituting the fourth power line PL4, and any one of the plurality of power lines constituting the fifth power line PL5.

In an embodiment of the disclosure, the display device 100 may include a flat display device, a curved display device in which a portion of the display unit 110 is curved, a flexible display device in which a portion of the display unit 110 is folded or bent, and a stretchable display device in which a portion of the display unit 110 is expanded/contracted.

In an embodiment of the disclosure, the display device 100 is a device which displays moving images or still images, and may include portable electronic devices such as a mobile phone, a smartphone, a tablet personal computer (PC), a smart watch, a watch phone, a portable multimedia player (PMP), a navigation system, and an ultra mobile computer (UMPC). In an embodiment of the disclosure, the display device 100 may include electronic devices such as a television, a notebook computer, a monitor, an advertisement board, and Internet of things (IOT).

FIG. 3 is a diagram illustrating a pixel in accordance with an embodiment of the disclosure. In FIG. 3, a pixel located on an ith horizontal line and a jth vertical line will be illustrated.

Referring to FIG. 3, a pixel PXij in accordance with an embodiment of the disclosure may be connected to corresponding signal lines SL1i, SL2i, SL3, SL4i, Elk, and DLj. For example, the pixel PXij may be connected to an ith first scan line SL1i, an ith second scan line SL2i, an ith third scan line SL3i, an ith fourth scan line SL4i, a kth emission control line ELk, and a jth data line DLj. In an embodiment, the pixel PXij may be further connected to the first power line PL1, the second power line PL2, the third power line PL3, the fourth power line PL4, and the fifth power line PL5.

The pixel PXij in accordance with the embodiment of the disclosure may include a light emitting element LD and a pixel circuit for controlling an amount of current supplied to the light emitting element LD.

The light emitting element LD may be connected between the first power line PL1 and the fifth power line PL5. In an example, a first electrode (or anode electrode) of the light emitting element LD may be electrically connected to the first power line PL1 via an eighth transistor M8, a third node N3, a first transistor M1, a second node N2, and a seventh transistor M7, and a second electrode (or cathode electrode) of the light emitting element LD may be electrically connected to the fifth power line PL5. The light emitting element LD may generate light with a luminance corresponding to an amount of current supplied from the first power line PL1 to the fifth power line PL5 via the pixel circuit.

The light emitting element LD may be selected as an organic light emitting diode. Also, the light emitting element LD may be selected as an inorganic light emitting diode such as a micro LED (light emitting diode) or a quantum dot light emitting diode. Also, the light emitting element LD may be an element configured with a combination of an organic material and an inorganic material. In FIG. 3, it is illustrated that the pixel PXij includes a single light emitting element LD. However, in another embodiment, the pixel PXij may include a plurality of light emitting elements LD, and the plurality of light emitting elements LD may be connected in series, parallel or series/parallel to each other.

The pixel circuit may include the first transistor M1, a second transistor M2, a third transistor M3, a fourth transistor M4, a fifth transistor M5, a sixth transistor M6, the seventh transistor M7, the eighth transistor M8, and a storage capacitor Cst.

A first electrode of the first transistor M1 (or driving transistor) may be connected to the first power line PL1 via the second node N2, and a second electrode of the first transistor M1 may be connected to the first electrode of the light emitting element LD via the third node N3. In addition, a gate electrode of the first transistor M1 may be connected to a first node N1. The first transistor M1 may control an amount of current supplied from the first driving power source VDD to the second driving power source VSS via the light emitting element LD, corresponding to a voltage of the first node N1.

The second transistor M2 (or switching transistor) may be connected between the data line DLj and the second node N2. In addition, a gate electrode of the second transistor M2 may be electrically connected to the first scan line SL1i. The second transistor M2 may be turned on in case that an enable first scan signal GW is supplied to the first scan line SL1i, to electrically connect the data line DLj and the second node N2 to each other.

The third transistor M3 (or diode transistor) may be connected between the first node N1 and the third node N3. In addition, a gate electrode of the third transistor M3 may be electrically connected to the second scan line SL2i. The third transistor M3 may be turned on in case that an enable second scan signal GC is supplied to the second scan line SL2i, to electrically connect the first node N1 and the third node N3 to each other. In case that the third transistor M3 is turned on, the first transistor M1 may be diode-connected.

A first electrode of the fourth transistor M4 may be connected to the first node N1, and a second electrode of the fourth transistor M4 may be electrically connected to the second power line PL2. In addition, a gate electrode of the fourth transistor M4 may be electrically connected to the third scan line SL3i. The fourth transistor M4 may be turned on in case that an enable third scan signal GI is supplied to the third scan line SL3i, to supply the voltage of the first initialization power source Vint1 to the first node N1.

A first electrode of the fifth transistor M5 may be connected to the first electrode of the light emitting element LD, and a second electrode of the fifth transistor M5 may be electrically connected to the third power line PL3. In addition, a gate electrode of the fifth transistor M5 may be electrically connected to the fourth scan line SL4i. The fifth transistor M5 may be turned on in case that an enable fourth scan signal GB is supplied to the fourth scan line SL4i, to supply the voltage of the second initialization power source Vint2 to the first electrode of the light emitting element LD.

In case that the voltage of the second initialization power source Vint2 is supplied to the first electrode of the light emitting element LD, a parasitic capacitor of the light emitting element LD may be discharged. As a residual voltage charged in the parasitic capacitor of the light emitting element LD is discharged (or removed), unintended minute emission can be prevented. Thus, the black expression ability of the pixel PXij can be improved.

A first electrode of the sixth transistor M6 may be electrically connected to the fourth power line PL4 (or bias power line), and a second electrode of the sixth transistor M6 may be connected to the second node N2. In addition, a gate electrode of the sixth transistor M6 may be electrically connected to the fourth scan line SL4i. The sixth transistor M6 may be turned on in case that the enable fourth scan signal GB is supplied to the fourth scan line SL4i, to electrically connect the fourth power line PL4 and the second node N2 to each other.

A first electrode of the seventh transistor M7 may be electrically connected to the first power line PL1, and a second electrode of the seventh transistor M7 may be connected to the second node N2. In addition, a gate electrode of the seventh transistor M7 may be electrically connected to the emission control line ELk. The seventh transistor M7 may be turned off in case that a disable emission control signal EM is supplied to the emission control line ELk, and be turned on in case that an enable emission control signal EM is supplied to the emission control line ELk.

The eighth transistor M8 may be connected between the third node N3 and the first electrode of the light emitting element LD. In addition, a gate electrode of the eighth transistor M8 may be electrically connected to the emission control line ELk. The eighth transistor M8 may be turned off in case that the disable emission control signal EM is supplied to the emission control line ELk, and be turned on in case that the enable emission control signal EM is supplied to the emission control line ELk.

The storage capacitor Cst may be connected between the first power line PL1 and the first node N1. The storage capacitor Cst may store a voltage applied to the first node N1.

In an embodiment, the first transistor M1, the second transistor M2, the fifth transistor M5, the sixth transistor M6, the seventh transistor M7, and the eighth transistor M8 may be implemented with a poly-silicon semiconductor transistor. For example, the first transistor M1, the second transistor M2, the fifth transistor M5, the sixth transistor M6, the seventh transistor M7, and the eighth transistor M8 may include a poly-silicon semiconductor layer formed as an active layer (channel) through a low temperature poly-silicon (LTPS) process. In addition, the first transistor M1, the second transistor M2, the fifth transistor M5, the sixth transistor M6, the seventh transistor M7, and the eighth transistor M8 may be implemented with a P-type transistor (e.g., a PMOS transistor). Accordingly, a gate-on voltage at which the first transistor M1, the second transistor M2, the fifth transistor M5, the sixth transistor M6, the seventh transistor M7, and the eighth transistor M8 are turned on may have a logic low level. The poly-silicon semiconductor transistor may be applied to a switching element which requires fast switching because the poly-silicon semiconductor transistor has an advantage of high response speed.

In an embodiment, the third transistor M3 and the fourth transistor M4 may be formed with an oxide semiconductor transistor. For example, the third transistor M3 and the fourth transistor M4 may be implemented with an N-type oxide semiconductor transistor (e.g., an NMOS transistor), and include an oxide semiconductor layer as an active layer. Accordingly, a gate-on voltage at which the third transistor M23 and the fourth transistor M24 are turned on may have a logic high level.

The oxide semiconductor transistor can be formed through a low temperature process, and have a charge mobility lower than a charge mobility of the poly-silicon semiconductor transistor. For example, the oxide semiconductor transistor has an excellent off-current characteristic. Thus, in case that the third transistor M3 and the fourth transistor M4 are implemented with the oxide semiconductor transistor, current leakage from the first node N1 according to low frequency driving can be minimized, and accordingly, display quality can be improved.

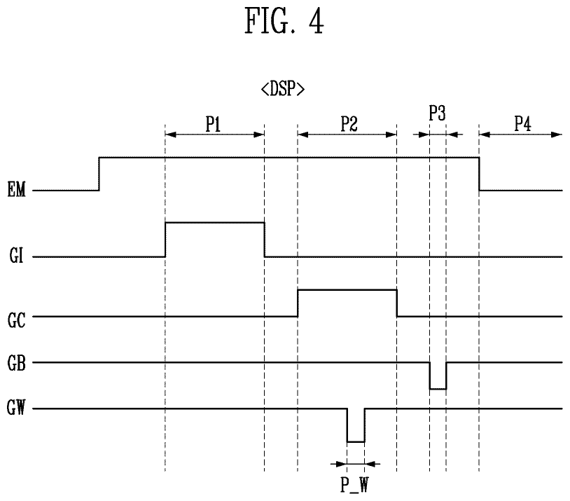

FIG. 4 is a waveform diagram illustrating an embodiment of a method of driving the pixel shown in FIG. 3 during a display scan period. The display scan period DSP may be included in an active period of a frame.

Referring to FIGS. 3 and 4, the display scan period DSP may include a first period P1, a second period P2, a third period P3, and a fourth period P4. The first period P1, the second period P2, and the third period P3 may be set as a non-emission period, and the fourth period P4 may be set as an emission period.

During the first period P1 to the third period P3, the disable emission control signal EM may be supplied to the emission control line ELk. In case that the disable emission control signal EM is supplied to the emission control line ELk, the seventh transistor M7 and the eighth transistor M8 may be turned off. In case that the seventh transistor M7 and the eighth transistor M8 are turned off, an electrical connection between the first power line PL1 and the light emitting element LD may be interrupted, and accordingly, the light emitting element LD may be set to be in a non-emission state.

During the first period P1, the enable third scan signal GI may be supplied to the third scan line SL3i. In case that the enable third scan signal GI is supplied to the third scan line SL3i, the fourth transistor M4 may be turned on. In case that the fourth transistor M4 is turned on, the voltage of the first initialization power source Vint1 of the second power line PL2 may be supplied to the first node N1.

During the second period P2, the enable second scan signal GC may be supplied to the second scan line SL2i, and accordingly, the third transistor M3 may be turned on. In case that the third transistor M3 is turned on, the first transistor M1 may be diode-connected.

In a writing period P_W overlapping with the second period P2, the enable first scan signal GW may be supplied to the first scan line SL1i. In case that the enable first scan signal GW is supplied to the first scan line SL1i, the second transistor M2 may be turned on. In case that the second transistor M2 is turned on, a data signal from the data line DLj may be supplied to the second node N2. The diode-connected first transistor M1 is maintained by the turned-on third transistor M3, and therefore, the first node N1 may have a voltage obtained by compensating for a threshold voltage of the first transistor M1 in the data signal.

During the third period P3, the enable fourth scan signal GB may be supplied to the fourth scan line SL4i. In case that the enable fourth scan signal GB is supplied to the fourth scan line SL4i, the fifth transistor M5 and the sixth transistor M6 may be turned on. In case that the fifth transistor M5 is turned on, the voltage of the second initialization power source Vint2 may be supplied to the first electrode of the light emitting element LD, and accordingly, the light emitting element LD may be initialized. In case that the sixth transistor M6 is turned on, the voltage of the bias power source Vbias may be supplied to the second node N2. In case that the voltage of the bias power source Vbias is supplied to the second node N2, the first transistor M1 may be set to be in an on-bias state.

In the fourth period P4, the enable emission control signal EM (or low level emission control signal) may be supplied to the emission control line ELk such that the seventh transistor M7 and the eighth transistor M8 are turned on. In case that the seventh transistor M7 and the eighth transistor M8 are turned on, a current flow path may be formed, a current flow path may be formed, which is connected to the fifth power line PL5 vias the first power line PL1, the seventh transistor M7, the first transistor M1, the eighth transistor M8, and the light emitting element LD. A driving current corresponding to the voltage of the first node N1 may flow through the light emitting element LD according to an operation of the first transistor M1, and the light emitting element LD may emit light with a luminance corresponding to the driving current.

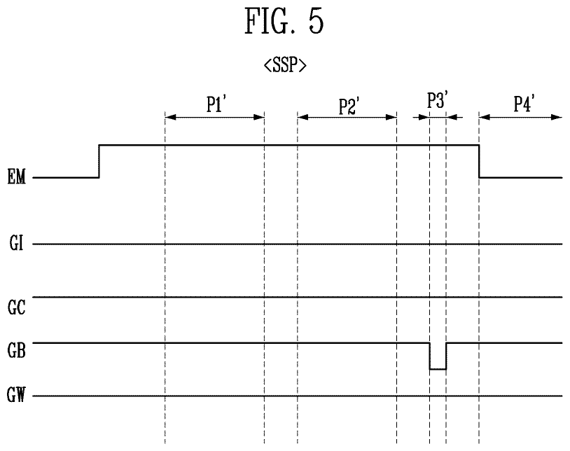

FIG. 5 is a waveform diagram illustrating an embodiment of a method of driving the pixel shown in FIG. 3 during a self-scan period. The self-scan period SSP is a period in which light is emitted while maintaining a voltage of a previously supplied data signal, and may be a period in which an image is re-displayed without shifting any frame. In an embodiment, a frame may include a display scan period DSP and at least one self-scan period SSP. The at least one self-scan period SSP may be successively disposed after the display scan period DSP. The self-scan period SSP may be included in a blank period of the frame

As compared with the display scan period DSP, a threshold voltage compensation operation and a data writing operation may be omitted in the self-scan period SSP, and an operation of applying a bias voltage to the first transistor M1 (and an operation of initializing the light emitting element LD) and an emission operation may be performed in the self-scan period SSP. The self-scan period SSP may be set to have a length equal or similar to a length of the display scan period DSP. The self-scan period SSP may include a first period P1′, a second period P2′, a third period P3′, and a fourth period P4′.

Referring to FIGS. 3 and 5, in the first period P1′ to the third period P3′, the disable emission control signal EM may be supplied to the emission control line ELk. In case that the disable emission control signal EM is supplied to the emission control line ELk, the seventh transistor M7 and the eighth transistor M8 may be turned off, and accordingly, the light emitting element LD may be set to be in the non-emission state.

In the first period P1′ to the third period P3′, the enable first scan signal GW, the enable second scan signal GC, and the enable third scan signal GI may not be supplied (or disable scan signals GW, GC, and GI may be supplied). Accordingly, in the first period P1′ to the third period P3′, the second transistor M2, the third transistor M3, and the fourth transistor M4 may be set to be in a turn-off state.

In the third period P3′, the enable fourth scan signal GB may be supplied to the fourth scan line SL4i. In case that the enable fourth scan signal GB is supplied to the fourth scan line SL4i, the fifth transistor M5 and the sixth transistor M6 may be turned on.

In case that the fifth transistor M5 is turned on, the voltage of the second initialization power source Vint2 may be supplied to the first electrode of the light emitting element LD, and accordingly, the light emitting element LD may be initialized. In case that the sixth transistor M6 is turned on, the voltage of the bias power source Vbias may be supplied to the second node N2. In case that the voltage of the bias power source Vbias is supplied to the second node N2, the first transistor M1 may be set to be in the on-bias state.

The above-described display device 100 in accordance with the embodiment of the disclosure can be driven in various driving frequencies (various frame frequencies) because a frame includes a display scan period DSP and a self-scan period SSP.

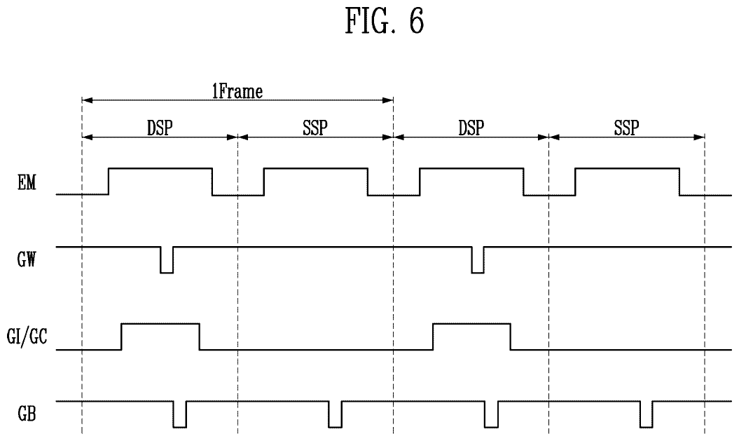

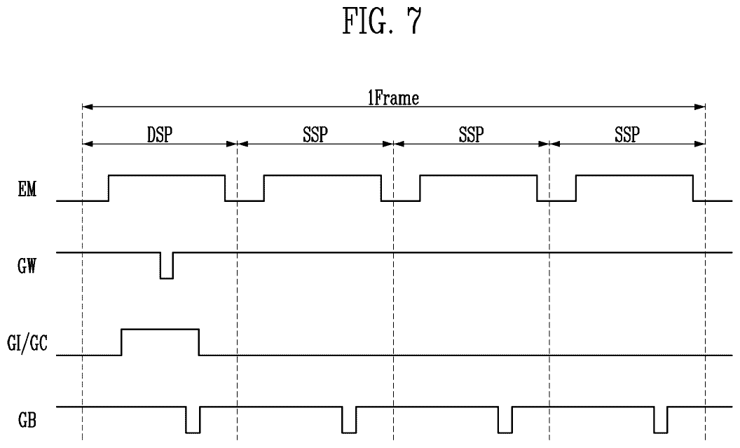

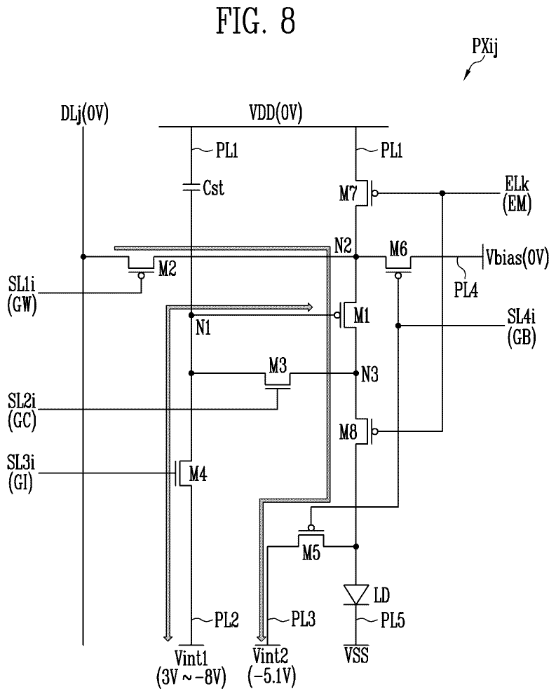

FIGS. 6 and 7 are diagrams illustrating an embodiment of signals supplied in an active period and a blank period. Scan signals GW, GC, GI, and GB shown in FIGS. 7 and 8 display whether the signals GW, GC, GI, and GB are to be supplied in a display scan period DSP and a self-scan period SSP. For convenience of description, a second scan signal GC and a third scan signal GI are illustrated as a single signal.

Referring to FIG. 6, a display scan period DSP and a self-scan period SSP may be included during a frame 1Frame. In the display scan period DSP, an emission control signal EM, an enable first scan signal GW, an enable second scan signal GC, an enable third scan signal GI, and an enable fourth scan signal GB may be supplied.

In the self-scan period SSP, the emission control signal EM and the enable fourth scan signal GB may be supplied. For example, the emission control signal EM and the enable fourth scan signal GB may be supplied in both the display scan period DSP and the self-scan period SSP, and the other scan signals GW, GC, and GI may be supplied in only the display scan period DSP.

In some embodiments, as the driving frequency of the display device 100 becomes lower (e.g., low frequency driving), the number of self-scan periods SSP included in a frame 1Frame may be increased as shown in FIG. 7, and accordingly, the number of times the emission control signal EM and the enable fourth scan signal GB are supplied in the frame 1Frame may be increased.

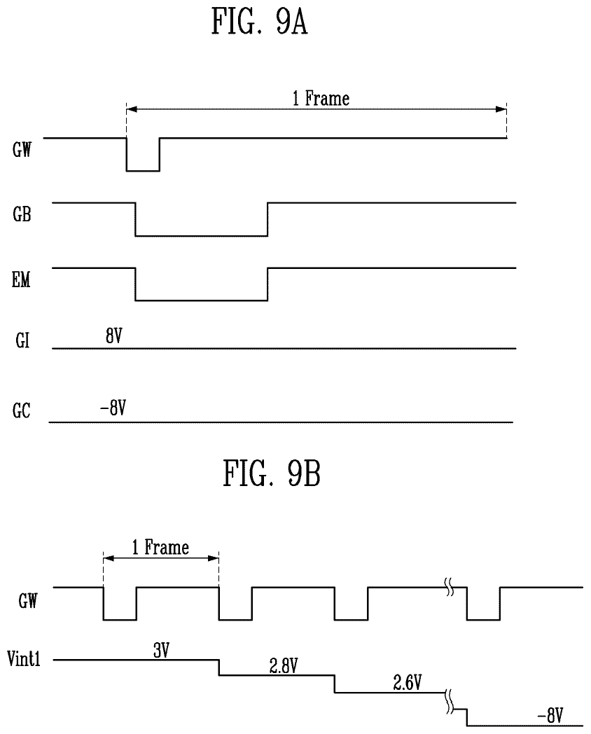

FIG. 8 is a diagram illustrating an embodiment of a voltage supplied to pixels in an inspection process of the pixels. FIGS. 9A and 9B are diagrams illustrating driving waveforms supplied to the pixels in the inspection process. The inspection process may be performed in the processing process of the display device 100. In an example, after transistors M1 to M8 included in each of the pixels PX are formed, the transistors M1 to M8 may go through the inspection process (when no light emitting element may be formed yet).

In the inspection process, a characteristic (e.g., a voltage-current characteristic) of the first transistors M1 may be detected, and whether the pixels PX are abnormal may be detected using the detected characteristic of the first transistors M1.

Referring to FIG. 8, during the inspection process, a first voltage may be supplied to the data line DLj (or the data lines DL1 to DLm), the first power line PL1, and the fourth power line PL4. The first voltage may be set as 0 V. During the inspection process, a second voltage may be supplied to the third power line PL3, and a voltage decreased from a third voltage to a fourth voltage may be supplied to the second power line PL2.

The second voltage may be set as a voltage, e.g., −5.1 V lower than the first voltage. The third voltage may be set as a voltage, e.g., 3 V higher than the first voltage. The fourth voltage may be set as a voltage, e.g., −8 V lower than the second voltage.

Referring to FIG. 9A, an enable first scan signal GW may be supplied to the first scan line SL1i in the inspection process. In addition, an enable fourth scan signal GB may be supplied to the fourth scan line SL4i, and an enable emission control signal EM may be supplied to the emission control line ELk such that the enable fourth scan signal GB and the enable emission control signal EM overlap with the enable first scan signal GW in time. The enable fourth scan signal GB and the enable emission control signal EM may be supplied during a partial period of a frame 1Frame period.

In addition, during a remaining period of the frame 1Frame period, a disable fourth scan signal GB may be supplied to the fourth scan line SL4i, and a disable emission control signal EM may be supplied to the emission control line ELk. The remaining period may be 98% or more of the frame 1Frame period, e.g., 97% to 99% of the frame 1Frame period.

In the inspection process, a disable second scan signal GC (i.e., a gate-off voltage (e.g., −8 V)) may be supplied to the second scan line SL2i. In case that the disable second scan signal GC is supplied to the second scan line SL2i, the third transistor M3 may be set to be in a turn-off state during the inspection process.

In the inspection process, an enable third scan signal GI (i.e., a gate-on voltage (e.g., 8 V)) may be supplied to the third scan line SL3i. In case that the enable third scan signal GI is supplied to the third scan line SL3i, the fourth transistor M4 may be set to be in a turn-on state during the inspection process.

Referring to FIG. 9B, the voltage supplied to the second power line PL2 during the inspection process may be decreased by a certain voltage for each frame. In an example, the voltage supplied to the second power line PL2 may be decreased by 0.2 V whenever the frame is changed. The voltage of the second power line PL2 may be gradually decreased from 3 V to −8 V.

An operation process will be described. The first node N1 may be set to 3 V during a first frame period, and the second transistor M2 may be turned on in case that the first enable scan signal GW is supplied. A current may flow from the data line DLj to the third power line PL3 via the second transistor M2, the first transistor M1, the eighth transistor M8, and the fifth transistor M5.

The first node N1 may be set to 2.8 V during a second frame period, and the second transistor M2 may be turned on in case that the enable first scan signal GW is supplied. A current may flow from the data line DLj to the third power line PL3 via the second transistor M2, the first transistor M1, the eighth transistor M8, and the fifth transistor M5.

The first node N1 may be set to 2.6 V during a third frame period, the second transistor M2 may be turned on in case that the enable first scan signal GW is supplied. A current may flow from the data line DLj to the third power line PL3 via the second transistor M2, the first transistor M1, the eighth transistor M8, and the fifth transistor M5.

The first node N1 may be set to −8 V during a fifty-fifth frame period, the second transistor M2 may be turned on in case that the enable first scan signal GW is supplied. A current may flow from the data line DLj to the third power line PL3 via the second transistor M2, the first transistor M1, the eighth transistor M8, and the fifth transistor M5.

A characteristic curve of the first transistor M1 may be obtained using a voltage (i.e., 3 V to −8 V) supplied to the gate electrode of the first transistor M1 and a current measured in the data line DLj during the inspection process. In addition, whether the pixels PX are abnormal may be determined using the characteristic curve of the first transistor M1. For example, during the inspection process, a characteristic curve of the first transistor included in each of the pixels PX, and whether the pixels PX are abnormal may be determined using the detected characteristic curve.

In case that the third transistor M3 is turned on during the inspection process, the first node N1 and the third node N3 may be electrically connected to each other. As a current is supplied toward the third node N3 from the first node N1 or as a current is supplied toward the first node N1 from the third node N3, a characteristic of the first transistor M1 may not be appropriately detected. To prevent this, in an embodiment of the disclosure, the third transistor M3 may be set to be in a turn-off state by supplying a gate-off voltage to the second scan line SL2i during the inspection process.

During the inspection process, by IR-drop of the first power line PL1, IR-drop of the fourth power line PL4, and the like, a current from the data line DLj may be supplied to the first power line PL1 and/or the fourth power line PL4, or a current from the first power line PL1 and/or the fourth power line PL4 may be supplied to the second node N2. The characteristic of the first transistor M1 may not be appropriately detected.

In an embodiment of the disclosure, to minimize influence of the first power line PL1 and the fourth power line PL4, the disable fourth scan signal GB may be supplied to the fourth scan line SL4i and the disable emission control signal EM may be supplied to the emission control line ELk during about 95% of the frame period. Thus, the time for which the first power line PL1 and the fourth power line PL4 are electrically connected to the second node N2 during the frame period can be minimized, and accordingly, the characteristic of the first transistor M1 can be more accurately detected.

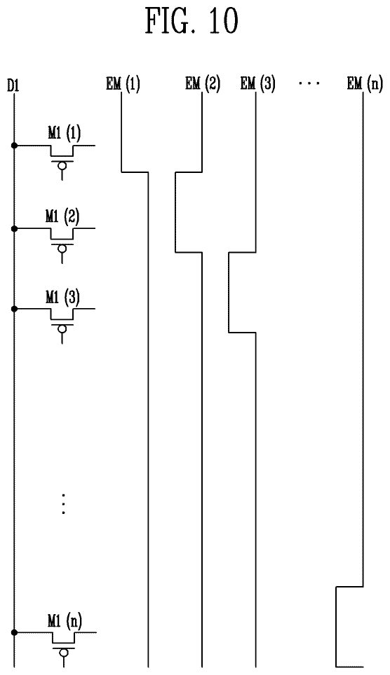

FIG. 10 is a diagram illustrating an example of an emission control signal supplied during an inspection period. In FIG. 10, a number included in “( )” in M1(1), M1(2), M1(3), . . . . M1(n) may mean a horizontal line on which a first transistor M1 is formed. In FIG. 10, a number included in “( )” in EM(1), EM(2), EM(3), . . . . EM(n) may mean a horizontal line on which an emission control signal is supplied. In FIG. 10, it is assumed that n emission control lines are included. In FIG. 10, for convenience of description, a first data line D1 is illustrated, and it is illustrated that the first data line D1 is directly connected to first transistors M1(1), M1(2), M1(3), . . . , and M1(n).

Referring to FIG. 10, an emission control signal may be sequentially supplied during an inspection period.

A current flowing through a first transistor M1(1) located on a first horizontal line in case that an enable emission control signal EM(1) is supplied to the first horizontal line. In an example, the current flowing through the first transistor M1(1) may be detected by an inspection apparatus electrically connected to the first data line D1.

A current flowing through a first transistor M1(2) located on a second horizontal line in case that an enable emission control signal EM(2) is supplied to the second horizontal line. In an example, the current flowing through the first transistor M1(2) may be detected by the inspection apparatus electrically connected to the first data line D1.

A current flowing through a first transistor M1(3) located on a third horizontal line in case that an enable emission control signal EM(3) is supplied to the third horizontal line. In an example, the current flowing through the first transistor M1(3) may be detected by the inspection apparatus electrically connected to the first data line D1.

A current flowing through a first transistor M1(n) located on an nth horizontal line in case that an enable emission control signal EM (n) is supplied to the nth horizontal line. In an example, the current flowing through the first transistor M1(n) may be detected by the inspection apparatus electrically connected to the first data line D1.

By using the above-described method, whether the pixels PX are abnormal can be detected in the inspection process.

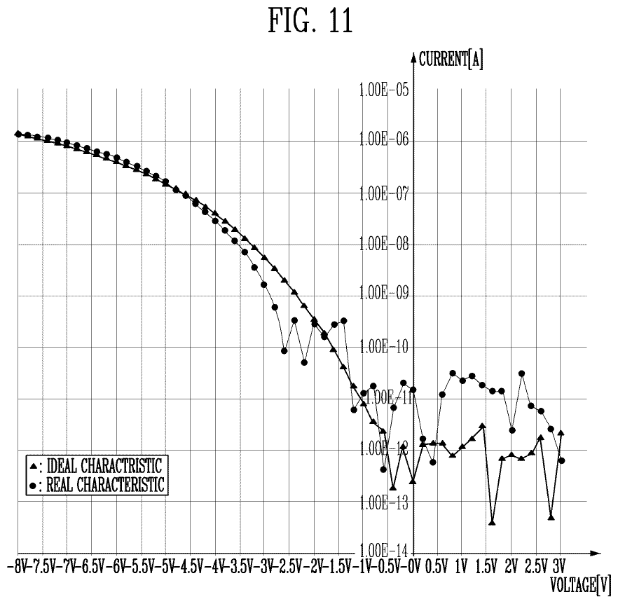

FIG. 11 is a diagram illustrating a characteristic curve of a first transistor, which is detected in the inspection process. In FIG. 11, an ideal characteristic may mean an ideal characteristic curve of the first transistor M1, which is obtained by considering IR-drop of the first power line PL1 and the fourth power line PL4. In FIG. 11, a real characteristic may mean a real characteristic curve of the first transistor M1, which is obtained by considering IR-drop of the first power line PL1 and the fourth power line PL4.

Referring to FIG. 11, a voltage of the second power line PL2 may be gradually decreased from 3 V to −8 V, and accordingly, an amount of current of the first transistor M1 included in each of the pixels PX may be differently set.

In an example, an amount of current flowing through the first transistor M1 may be increased as approaching the fourth voltage (i.e., −8 V) from the third voltage (i.e., 3 V). In the inspection process, an amount of current of first transistors M1 may be measured corresponding to a voltage supplied to the second power line PL2, using an inspection apparatus connected to the data lines DL1 to DLm, and a characteristic curve of the first transistors M1 may be generated corresponding to the measured amount of current. In addition, whether each of the pixels PX is abnormal may be determined using the characteristic curve of the first transistors M1.

In FIG. 11, an ideal characteristic curve of the first transistor M1 and a real characteristic curve of the first transistor M1 are illustrated. In case that the voltage supplied to the second power line PL2 has a relatively high voltage (e.g., about −2.5 V or higher), the characteristic of the first transistor M1 may not be accurately detected due to influence of IR-drop of the first power line PL1 and the fourth power line PL4. In the inspection process, whether the pixels PX are abnormal may be determined by considering such features.

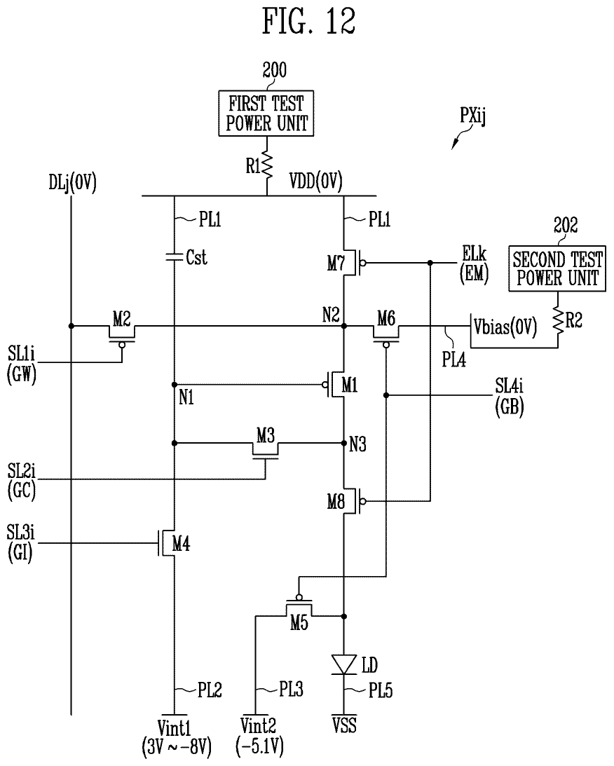

FIG. 12 is a diagram illustrating an embodiment in which a voltage is supplied to pixels in an inspection process of the pixels.

Referring to FIG. 12, in an inspection process, a first test power unit 200 may supply a first voltage to the first power line PL1 via a first resistor R1. An amount of current supplied from the second node N2 to the first power line PL1 and/or an amount of current supplied from the first power line PL1 to the second node N2 may be minimized in case that the seventh transistor M7 is turned on, and accordingly, the characteristic of the first transistor M1 can be stably detected. The first resistor R1 may have a resistance value of 100Ω to 100 MΩ.

In the inspection process, a second test power unit 202 may supply the first voltage to the fourth power line PL4 via a second resistor R2. An amount of current supplied from the second node N2 to the fourth power line PL4 and/or an amount of current supplied from the fourth power line PL4 to the second node N2 may be minimized in case that the sixth transistor M6 is turned on, and accordingly, the characteristic of the first transistor M1 can be stably detected. The second resistor R2 may have a resistance value of 100Ω to 100 MΩ.

In FIG. 12, it is illustrated that the first test power unit 200 and the second test power unit 202 are components separate from each other. However, the embodiment of the disclosure is not limited thereto. In another example, the first test power unit 200 and the second test power unit 202 may be integrated into a single power unit.

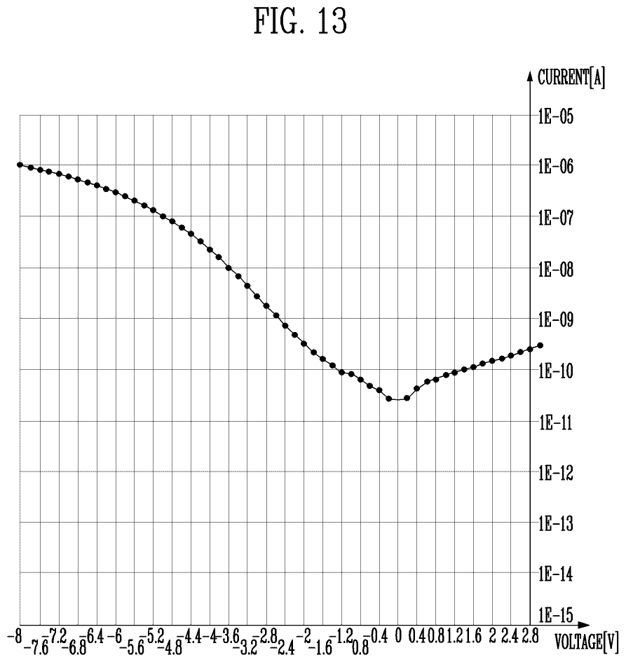

FIG. 13 is a diagram illustrating a characteristic curve of the first transistor, which is generated in the inspection process, in case that the voltage is supplied via a resistor as shown in FIG. 12.

Referring to FIG. 13, a voltage of the second power line PL2 may be gradually decreased from 3 V to −8 V, and accordingly, an amount of current of the first transistor M1 included in each of the pixels PX may be differently set.

In the inspection process, an amount of current of first transistors M1 may be measured corresponding to a voltage supplied to the second power line PL2, using an inspection apparatus connected to the data lines DL1 to DLm, and a characteristic curve of the first transistors M1 may be generated corresponding to the measured amount of current. In addition, whether each of the pixels PX is abnormal may be determined using the characteristic curve of the first transistors M1.

In case that the first voltage is supplied to the first power line PL1 and the fourth power line PL4 via the first resistor R1 and the second resistor R2, an amount of current introduced and/or discharged from the first power line PL1 and the fourth power line PL4 to the second node N2 can be minimized. As shown in FIG. 13, the characteristic of the first transistor M1 can be stably detected.

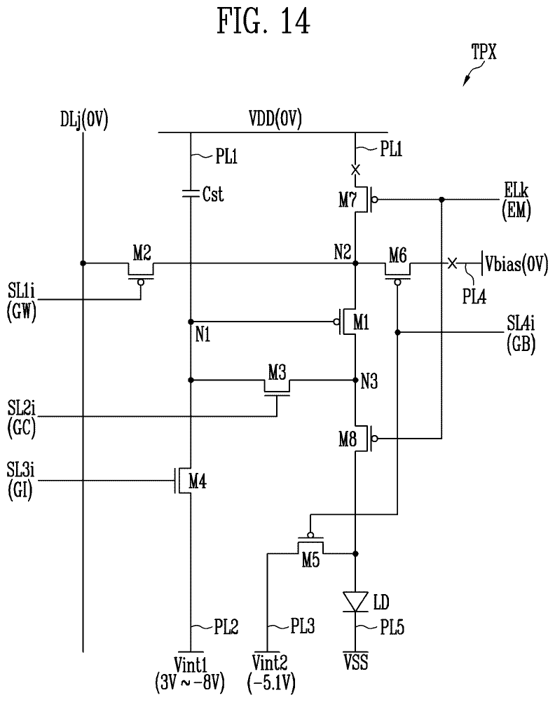

FIG. 14 is a diagram illustrating a test pixel in accordance with an embodiment of the disclosure.

Referring to FIG. 14, the display device 100 in accordance with the embodiment of the disclosure may include a test pixel TPX. The test pixel TPX may be included in the pixel unit 110, and be a pixel which displays no image.

In an example, the test pixel TPX may be a pixel for detecting a characteristic of a first transistor M1. A basic configuration of the test pixel PX may be substantially identical to the configuration of the pixel PXij described in FIG. 3. Therefore, the same or similar constituent elements will be designated by the same reference numerals, and detailed descriptions will be omitted.

A first power line PL1 included in the test pixel TPX may be electrically interrupted from a seventh transistor M7. In an example, the first power line PL1 may be cut off so as not to be electrically connected to the seventh transistor M7.

A fourth power line PL4 included in the test pixel TPX may be electrically interrupted from a sixth transistor M6. In an example, the fourth power line PL4 may be cut off so as not to be electrically connected to the sixth transistor M6.

As such, in case that a second node N2 is electrically interrupted from the first power line PL1 and the fourth power line PL4, the characteristic of the first transistor M1 can be more accurately detected. For example, in case that it is desirable to accurately detect the characteristic of the first transistor M1 in the inspection process, the test pixel TPX may be formed in the pixel unit 110. Additionally, no light emitting element LD may be included in the test pixel TPX.

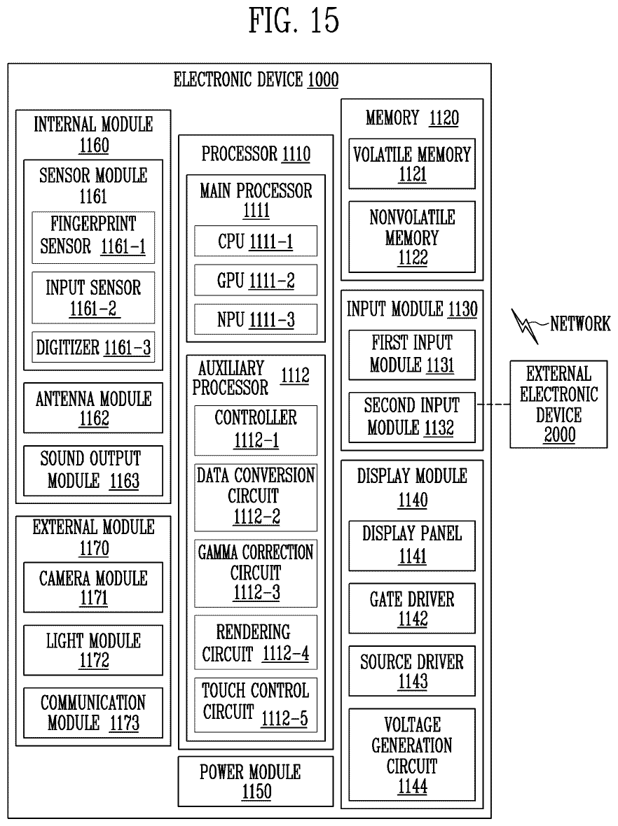

FIG. 15 is a diagram illustrating an electronic device in accordance with an embodiment of the disclosure.

Referring to FIG. 15, an electronic device 1000 in accordance with an embodiment of the disclosure may output various information through a display module 1140. In case that a processor 1110 executes an application stored in a memory 1120, the display module 1140 may provide application information to a user through a display panel 1141.

The processor 1110 may acquire an external input through an input module 1130 or a sensor module 1161, and execute an application corresponding to the external input. For example, in case that the user selects a camera icon (or camera application icon) displayed on the display panel 1141, the processor 1110 may acquire a user input through an input sensor 1161-2, and activate a camera module 1171. The processor 1110 may transfer, to the display module 1140, image data corresponding to a photographed image acquired through the camera module 1171. The display module 1140 may display an image corresponding to the photographed image through the display panel 1141.

In another example, in case that personal information authentication is executed in the display module 1140, a fingerprint sensor 1161-1 may acquire input fingerprint information as input data. The processor 1110 may compare the input data acquired through the fingerprint sensor 1161-1 with authentication data stored in the memory 1120, and execute an application according to a comparison result. The display module 1140 may display information executed according to a logic of the application through the display panel 1141. The fingerprint sensor 1161-1 may be located to acquire fingerprint information in the entire area of the display panel 1141.

In still another example, in case that a music streaming icon displayed on the display module 1140 is selected, the processor 1110 may acquire a user input through the input sensor 1161-2, and active a music streaming application stored in the memory 1120. In case that a music play command is input in the music streaming application, the processor 1110 may activate a sound output module 1163, thereby providing the user with sound information which accords with the music play command.

In the above, operations of the electronic device 1000 have been briefly described. Hereinafter, components of the electronic device 1000 will be described in detail. Some of the components of the electronic device 1000, which will be described later, may be integrated to be provided as one component, and one component may be separated into two or more components to be provided.

The electronic device 1000 may communicate with an external electronic device 2000 through a network (e.g., a short-range wireless communication network or a long-range wireless communication network). In an embodiment, the electronic device 1000 may include the processor 1110, the memory 1120, the input module 1130, the display module 1140, a power module 1150, an internal module 1160, and an external module 1170. In an embodiment, at least one of the above-described components may be omitted, or one or more other components may be added. In an embodiment, some components (e.g., the sensor module 1161, an antenna module 1162, and/or the sound output module 1163) among the above-described components may be integrated in another component (e.g., the display module 1140).

The processor 1110 may control at least another component (e.g., a hardware or software component) of the electronic device 1000, which is connected to the processor 1110, by executing software, and perform various processing or calculations. In an embodiment, as at least a portion of the data processing and calculations, the processor 1110 may store, in a volatile memory 1121, a command or data, received from another component (e.g., the input module 1130, the sensor module 1161, or a communication module 1173), process the command or data, stored in the volatile memory 1121, and store result data in a nonvolatile memory 1122.

The processor 1110 may include a main processor 1111 and an auxiliary processor 1112. The main processor 1111 may include a central processing unit (CPU) 1111-1. The main processor 1111 may further include at least one of a graphic processing unit (GPU) 1111-2, a communication processor (CP), or an image signal processor (ISP). The main processor 1111 may further include a neural processing unit (NPU) 1111-3. The NPU 1111-3 is a processor specified for processing an artificial intelligence (AI) model, and the AI model may be generated through machine learning. The AI model may include a plurality of artificial neural network layers. An artificial neural network may be a deep neural network (DNN), a convolutional neural network (CNN), a recurrent neural network (RNN), a restricted boltzman machine (RBM), a deep belief network (DBN), a bidirectional recurrent deep neural network (BRDNN), a deep Q-networks, or one of two or more combinations thereof, but embodiments are not necessarily limited thereto. The AI model may additionally or alternatively include a software structure, in addition to a hardware structure. At least two of the above-described processing units and the above-described processors may be implemented into one integrated component (e.g., a single chip), or be implemented as components (e.g., a plurality of chips) independent from each other.

The auxiliary processor 1112 may include a controller 1112-1. The controller 1112-1 may include an interface conversion circuit and a timing control circuit. In an example, the auxiliary processor 1112 may include the timing controller 120 shown in FIG. 1. At least some functions (or components) of the timing controller 120 may be included in the controller 1112-1, a data conversion circuit 1112-2, a gamma correction circuit 1112-3, a rendering circuit 1112-4, a touch control circuit 1112-5, and the like.

The controller 1112-1 may receive an image signal from the main processor 1111, and convert a data format of the image signal to be suitable for interface specifications with the display module 1140, thereby outputting image data. The controller 1112-1 may output various control signals for driving of the display module 1140.

The auxiliary processor 1112 may further include the data conversion circuit 1112-2, the gamma correction circuit 1112-3, the rendering circuit 1112-4, the touch control circuit 1112-5, and the like. The data conversion circuit 1112-2 may receive image data from the controller 1112-1, and compensate for the image data such that an image is displayed with a desired luminance according to a characteristic of the electronic device 1000 or a setting of the user or convert the image data for the purpose of reduction of power consumption, afterimage compensation, or the like.

The gamma correction circuit 1112-3 may convert image data, a gamma reference voltage, or the like such that an image displayed in the electronic device 1000 has a desired gamma characteristic. The rendering circuit 1112-4 may receive image data from the controller 1112-1, and render the image data by considering a pixel arrangement of the display panel 1141, and the like, applied to the electronic device 1000.

The touch control circuit 1112-5 may supply a touch signal to the input sensor 1161-2, and be supplied with a sensing signal from the input sensor 1161-2, corresponding to the touch signal.

At least one of the data conversion circuit 1112-2, the gamma correction circuit 1112-3, the rendering circuit 1112-4, or the touch control circuit 1112-5 may be integrated in another component (e.g., the main processor 1111 or the controller 1112-4). At least one of the data conversion circuit 1112-2, the gamma correction circuit 1112-3, or the rendering circuit 1112-4 may be integrated into a source driver 1143 which will be described later.

The memory 1120 may store various data used by at least one component (e.g., the processor 1110 or the sensor module 1161) of the electronic device 1000, and input or output data about a command associated with the various data. Also, various setting data corresponding to the setting of the user the memory 1120. The memory 1120 may include at least one of the volatile memory 1121 or the nonvolatile memory 1122.

The input module 1130 may receive a command or data to be used in a component (e.g., the processor 1110, the sensor module 1161, or the sound output module 1163) of the electronic device 1000 from an outside (e.g., the user or the external electronic device 2000) of the electronic device 1000.

The input module 1130 may include a first input module 1131 to which a command or data is input from the user and a second input module 1132 to which a command or data is input from the external electronic device 2000. The first input module 1131 may include a microphone, a mouse, a keyboard, a key (e.g., a button), or a pen (e.g., a passive pen or an active pen). The second input module 1132 may support a specified protocol capable of connecting the electronic device 1000 to the external electronic device 2000 by wired or wireless. The second input module 1132 may include a high definition multimedia interface (HDMI), a universal serial bus (USB) interface, an SD card interface, or an audio interface. The second input module 1132 may include a connector, e.g., an HDMI connector, a USB connector, an SD card connector, or an audio connector (e.g., a headphone connector), which can physically connect the electronic device 1000 to the external electronic device 2000.

The display module 1140 may visually provide information to the user. The display module 1140 may include the display panel 1141, a gate driver 1142, the source driver 1143, and a voltage generating circuit 1144. The display module 1140 may further include a window for protecting the display panel 1141, a chassis, and a bracket. The display module 1140 may include at least some components of the display device 100 shown in FIG. 1.

The display panel 1141 (or display) may include a liquid crystal display panel, an organic light emitting display panel, or an inorganic light emitting display panel, and the kind of the display panel 1141 is not particularly limited. The display panel 1141 may be of a rigid type or a flexible type in which the display panel 1141 is rollable or foldable. The display module 1140 may further include a supporter for supporting the display panel 1141, a bracket, a heat dissipation member, or the like. The display panel 1141 may include the pixel unit 110 shown in FIG. 1.

The display panel 1141 may include the pixels PX shown in FIG. 1. Also, the display panel 1141 may include the test pixel TPX shown in FIG. 14. Whether the pixels PX included in the display panel 1141 are abnormal may be determined while going through the inspection process described with reference to FIGS. 8 to 12.

The gate driver 1142 is a driving chip, and may be mounted in the display panel 1141. Also, the gate driver 1142 may be integrated in the display panel 1141. For example, the gate driver 1142 may include an Amorphous Silicon TFT Gate (ASG) driver circuit, a Low Temperature Polycrystalline Silicon (LTPS) TFT gate driver circuit, or an Oxide Semiconductor TFT Gate (OSG) driver circuit, which is embedded in the display panel 1141. The gate driver 1142 may receive a control signal from the controller 1112-1, and output scan signals to the display panel 1141 in response to the control signal. The gate driver 1142 may include the scan driver 130 shown in FIG. 1.

The display module 1140 may further include an emission driver. The emission driver may correspond to the emission driver 150 shown in FIG. 1. The emission driver may output an emission control signal to the display panel 1141 in response to a control signal received from the controller 1112-1. The emission driver may be formed separately from the gate driver 1142, or be integrated in the gate driver 1142.

The source driver 1143 may receive a control signal from the controller 1112-1, and convert image data into an analog voltage (e.g., a data voltage) and then output data voltages to the display panel 1141 in response to the control signal. The source driver 1143 may include the data driver 140 shown in FIG. 1.

The source driver 1143 may be integrated in another component (e.g., the controller 1112-1). Functions of the interface conversion circuit and the timing control circuit of the controller 1112-1, which are described above, may be integrated in the source driver 1143. The voltage generating circuit 1144 may output various voltages for driving of the display panel 1141. The voltage generating circuit 1144 may include the power supply 160 shown in FIG. 1.

In an embodiment, the source driver 1143 may convert data corresponding to red (R), green (G), and blue (B), included in image data received from the processor 1110, into a red data signal (or data voltage), a green data signal, and a blue data signal, and provide the red data signal, the green data signal, and the blue data signal to a plurality of pixel columns included in the display panel 1141 during a horizontal period.

The power module 1150 may supply power to at least one component of the electronic device 1000. The power module 1150 may include a battery for charging a power voltage. The battery may include a primary cell which is not rechargeable, a secondary cell which is rechargeable, or a fuel cell. The power module 1150 may include a power management integrated circuit (PMIC). The PMIC may supply an optimized power source to each of the above-described modules and modules which will be described later. The power module 1150 may include a wireless power transmission/reception member electrically connected to the battery. The wireless power transmission/reception member may include a plurality of coil-shaped antenna radiators. At least some components of the power module 1150 and the voltage generating circuit 1144 may be provided to be integrated into one. The voltage generating circuit 1144 may be included in the power module 1150.

The electronic device 1000 may further include the internal module 1160 and the external module 1170. The internal module 1160 may include the sensor module 1161, the antenna module 1162, and the sound output module 1163. The external module 1170 may include the camera module 1171, a light module 1172, and the communication module 1173.

The sensor module 1161 may sense an input caused by a body of the user or an input caused by a pen in the first input module, and generate an electrical signal or a data value, which corresponds to the input. The sensor module 1161 may include at least one of the fingerprint sensor 1161-1, the input sensor 1161-2, or a digitizer 1161-3.

The fingerprint sensor 1161-1 may generate a data value corresponding to a fingerprint of the user.

The input sensor 1161-2 may generate a data value corresponding to coordinate information of the input caused by the body of the user or the input caused by the pen. The input sensor 1161-2 may generate, as a data value, a capacitance variation caused by the input. The input sensor 1161-2 may sense an input caused by a passive pen, or transmit/receive data to/from an active pen.

The input sensor 1161-2 may measure a biometric signal such as pressure, moisture or body fat. For example, in case that the user does not move for a constant time while a body part of the user is in contact with a sensor layer or a sensing panel, the input sensor 1161-2 may output information which the user wants to the display module 1140 by sensing a biometric signal, based on a change in electric field, caused by the body part.

The digitizer 1161-3 may generate a data value corresponding to the coordinate information of the input caused by the pen. The digitizer 1161-3 may generate, as a data value, an electromagnetic variation caused by the input. The digitizer 1161-3 may sense an input caused by the passive pend, or transmit/receive data to/from the active pen.

At least one of the fingerprint sensor 1161-1, the input sensor 1161-2, or the digitizer 1161-3 may be implemented as a sensor layer formed on the display panel 1141 through a continuous process. At least one of the fingerprint sensor 1161-1, the input sensor 1161-2, or the digitizer 1161-3 may be located at an upper side of the display panel 1141, and any one, e.g., the digitizer 1161-3 among the fingerprint sensor 1161-1, the input sensor 1161-2, and the digitizer 1161-3 may be located at a lower side of the display panel 1141.

At least two of the fingerprint sensor 1161-1, the input sensor 1161-2, and the digitizer 1161-3 may be formed to be integrated into one sensing panel through a same process. In case that at least two of the fingerprint sensor 1161-1, the input sensor 1161-2, and the digitizer 1161-3 are integrated into one sensing panel, the sensing panel may be located between the display panel 1141 and the window located at an upper side of the display panel 1141. In accordance with an embodiment, the sensing panel may be located on the window, and the position of the sensing panel is not particularly limited.

At least one of fingerprint sensor 1161-1, the input sensor 1161-2, or the digitizer 1161-3 may be built in the display panel 1141. That is, at least one of fingerprint sensor 1161-1, the input sensor 1161-2, or the digitizer 1161-3 may be simultaneously formed through a process of forming elements (e.g., a light emitting element, a transistor, and the like) included in the display panel 1141.

Besides, the sensor module 1161 may generate an electrical signal or a data value, which corresponds to an internal state or an external state of the electronic device 1000. The sensor module 1161 may further include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1162 may include one or more antennas for transmitting a signal or power to the outside or receiving a signal or power from the outside. In accordance with an embodiment, the communication module 1173 may transmit a signal to the external electronic device or receive a signal from the external electronic device through an antenna suitable for a communication scheme. An antenna pattern of the antenna module 1162 may be integrated in one component (e.g., the display panel 1141) of the display module 1140, the input sensor 1161-2, or the like.

The sound output module 1163 is a device for outputting a sound signal to the outside of the electronic device 1000, and include, for example, a speaker used for a general purpose such as multimedia playback or transcription playback and a receiver used for only call reception. The receiver may be integrally formed with the speaker or be formed separately from the speaker. A sound output pattern of the sound output module 1163 may be integrated in the display module 1140.

The camera module 1171 may photograph a still image and a moving image. The camera module 1171 may include one or more lenses, an image sensor, or an image signal processor. The camera module 1171 may further include an infrared camera capable of measuring existence of the user, a position of the user, eyes of the user, or the like.

The light module 1172 may provide light. The light module 1172 may include a light emitting diode or a xenon lamp. The light module 1172 may operate in linkage with the camera module 1171 or operate independently from the camera module 1171.

The communication module 1173 may establish a wired or wireless communication channel between the electronic device 1000 and the external electronic device 2000, and support communication performance through the established communication channel. The communication module may include any one or all of a wireless communication module such as a cellular communication module, a short-range wireless communication module, or a global navigation satellite system (GNSS) communication module, and a wired communication module such as a local area network (LAN) communication module or a power line communication (PLC) module. The communication module 1173 may communicate with the external electronic device 2000 through a short-range communication network such as Bluetooth™, wireless-fidelity (WiFi) direct, or infrared data association (IrDA), or a long-range communication network such as a cellular network, Internet, or a computer network (e.g., LAN or wide area network (WAN)). The above-described several kinds of communication modules may be implemented into one chip or be implemented as separate chips, respectively.

The input module 1130, the sensor module 1161, the camera module 1171, and the like may be used to control an operation of the display module 1140 in linkage with the processor 1110.

The processor 1110 may output a command or data to the display module 1140, the sound output module 1163, the camera module 1171, or the light module 1172, based on input data received from the input module 1130. For example, the processor 1110 may generate image data, corresponding to input data applied through a mouse, an active pen, or the like, and output the image data to the display module 1140. Alternatively, the processor 1110 may generate command data, corresponding to the input data, and output the command data to the camera module 1171 or the light module 1172. In case that no input data is received from the input module 1130, the processor 1110 may change the operation mode of the electronic device 1000 to a low power mode or a sleep mode, thereby reducing power consumed in the electronic device 1000.

The processor 1110 may output a command or data to the display module 1140, the sound output module 1163, the camera module 1171, or the light module 1172, based on sensing data received from the sensor module 1161. For example, the processor 1110 may compare authentication data applied by the fingerprint sensor 1161-1 with authentication data stored in the memory 1120, and then execute an application according to a comparison result. The processor 1110 may execute a command or output corresponding image data to the display module 1140, based on sensing data sensed by the input sensor 1161-2 or the digitizer 1161-3. In case that a temperature sensor is included in the sensor module 1161, the processor 1110 may receive temperature data about a temperature measured from the sensor module 1161, and further perform luminance correction on image data, based on the temperature data.

The processor 1110 may receive measurement data about existence of the user, a position of the user, eyes of the user, or the like from the camera module 1171. The processor 1110 may further perform luminance correction on image data, based on the measurement data. For example, the process 1110 which decides the existence of the user through an input from the camera module 1171 may output image data of which luminance is corrected to the display module 1140 through the data conversion circuit 1112-2 or the gamma correction circuit 1112-3.

At least some of the above-described components may be connected to each other and communicate signals (e.g., commands or data) therebetween through an inter-peripheral communication scheme, e.g., a bus, a general purpose input/output (GPIO), a serial peripheral interface (SPI), a mobile industry processor interface (MIPI), or an ultra path interconnect (UPI) link. The processor 1110 may communicate with the display module 1140 through an appointed interface, and use any one of the above-described communication schemes. However, the present disclosure is not limited to the above-described communication schemes.

In the display device and the method of inspecting the display device, and the electronic device in accordance with the embodiments of the disclosure, a diode transistor (i.e., third transistor M3 in FIGS. 3, 8, 12 and 14) included in a pixel is set to be in a turn-off state during an inspection process, and accordingly, a characteristic of a driving transistor (i.e., first transistor M1 in FIGS. 3, 8, 12 and 14) can be stably detected.

Also, in the display device and the method of inspecting the display device, and the electronic device in accordance with the embodiments of the disclosure, a voltage is supplied to a power line via a resistor during an inspection process, so that a characteristic of a driving transistor can be detected while minimizing influence of the power line.

Also, in the display device and the method of inspecting the display device, and the electronic device in accordance with the embodiments of the disclosure, a test pixel is formed, and the test pixel and some power lines are electrically interrupted from each other, so that a characteristic of a driving transistor can be detected.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A method of inspecting a display device,
wherein the display device includes pixels each including: a first transistor including a gate electrode connected to a first node, a first electrode connected to a first power line via a second node, and a second electrode connected to a third node; a second transistor connected between a data line and the second node, the second transistor including a gate electrode connected to a first scan line; a third transistor connected between the first node and the third node, the third transistor including a gate electrode connected to a second scan line; a fourth transistor connected between the first node and a second power line, the fourth transistor including a gate electrode connected to a third scan line; a fifth transistor connected between the third node and a third power line, the fifth transistor including a gate electrode connected to a fourth scan line; and a sixth transistor connected between the second node and a fourth power line, the sixth transistor including a gate electrode connected to the fourth scan line, and
wherein, during an inspection process of the pixels,
a first voltage is supplied to the data line, the first power line, and the fourth power line, a second voltage is supplied to the third power line, and a voltage decreased from a third voltage to a fourth voltage is supplied to the second power line; and
a gate-off voltage is supplied to the second scan line such that the third transistor is turned off.

2. The method of claim 1, wherein the first voltage is 0 voltage (V).

3. The method of claim 1, wherein the second voltage is a voltage lower than the first voltage.

4. The method of claim 1, wherein the third voltage is a voltage higher than the first voltage, and the fourth voltage is a voltage lower than the second voltage.

5. The method of claim 1, wherein the voltage supplied to the second power line is decreased by a certain voltage for each frame.

6. The method of claim 1, wherein each of the pixels further includes:
a seventh transistor connected between the first power line and the second node, the seventh transistor including a gate electrode connected to an emission control line; and
an eighth transistor connected between the third node and the fifth transistor, the eighth transistor including a gate electrode connected to the emission control line.

7. The method of claim 6, wherein, during the inspection process, an enable first scan signal is supplied to the first scan line such that the second transistor is turned on at least once in a frame period, and
wherein, during the inspection process, a gate-on voltage is supplied to the third scan line such that the fourth transistor is turned on.

8. The method of claim 7, wherein an enable emission control signal is supplied to the emission control line to overlap with the enable first scan signal in time such that the seventh transistor and the eighth transistor are turned on during a partial period of the frame period, and a disable emission control signal is supplied to the emission control line such that the seventh transistor and the eighth transistor are turned off during a remaining period of the frame period.

9. The method of claim 8, wherein the remaining period is 95% to 99% of the frame period.

10. The method of claim 8, wherein an enable fourth scan signal is supplied to the fourth scan line such that the sixth transistor is turned on during the partial period, and a disable fourth scan signal is supplied to the fourth scan line such that the sixth transistor is turned off during the remaining period.

11. The method of claim 1, wherein the first voltage is supplied to the first power line via a first resistor, and
wherein the first voltage is supplied to the fourth power line via a second resistor.

12. The method of claim 11, wherein the first resistor and the second resistor each have a resistance value of 100 ohms (Ω) to 100 megaohms (MΩ).

13. A method of inspecting a display device including a pixel, the method comprising:
supplying different voltages to a gate electrode of a driving transistor of the pixel for different frames; and
sensing an amount of current flowing through the driving transistor while allowing a switching transistor, of the pixel, connected between a data line and a first electrode of the driving transistor to be turned on during a partial period for each frame,
wherein a diode transistor, of the pixel, located between the gate electrode and a second electrode of the driving transistor is set to be in a turn-off state.

14. The method of claim 13, wherein a first voltage is supplied to a first power line and a bias power line, which are electrically connected to the first electrode of the driving transistor.

15. The method of claim 14, wherein the first voltage is supplied to the data line.

16. The method of claim 14, wherein the first voltage is supplied to the first power line via a first resistor, and
wherein the first voltage is supplied to the bias power line via a second resistor.

17. The method of claim 16, wherein the first resistor and the second resistor each have a resistance value of 100Ω to 100 MΩ.

18. An electronic device comprising:
a display panel including pixels, which display an image, and a test pixel, which does not display the image,
wherein the test pixel includes:
a first transistor including a gate electrode connected to a first node, a first electrode connected to a second node, and a second electrode connected to a third node;
a storage capacitor connected between a first power line and the first node;
a second transistor connected between a data line and the second node, the second transistor including a gate electrode connected to a first scan line;
a third transistor connected between the first node and the third node, the third transistor including a gate electrode connected to a second scan line;
a fourth transistor connected between the first node and a second power line, the fourth transistor including a gate electrode connected to a third scan line;
a fifth transistor connected between the third node and a third power line, the fifth transistor including a gate electrode connected to a fourth scan line;
a sixth transistor including a second electrode connected to the second node and a gate electrode connected to the fourth scan line;
a seventh transistor including a second electrode connected to the second node and a gate electrode connected to an emission control line; and
an eighth transistor connected between the third node and the fifth transistor, the eighth transistor including a gate electrode connected to the emission control line, and
wherein a first electrode of the seventh transistor is not electrically connected to the first power line.

19. The electronic device of claim 18, wherein a first electrode of the sixth transistor is not electrically connected to a separate power line.
